(19) United States
(12) Patent Application Publication
(10) Pub. No.: US 2004/0188241 A1
(43) Pub. Date: Sep. 30, 2004

(54) Method of depositing aluminium nitride

(76) Inventors: Paul Rich, Gloucestershire (GB); Claire Louise Wiggins, Lincolnshire (GB)

Correspondence Address: Volentine Francos, Suite 150, 12200 Sunrise Valley Drive, Reston, VA, 20191, US

(21) Appl. No.: 10/482,970

(22) PCT Filed: Jun. 20, 2002
(86) PCT No.: PCT/GB02/02946

(30) Foreign Application Priority Data
Jul. 7, 2001 (GB) 0116688.3

(51) Int. Cl. C23C 14/00; C23C 14/32

(52) U.S. Cl. 204/192.12

(57) ABSTRACT

A method of depositing crystallographically orientated aluminium nitride. Aluminium nitride is sputter deposited from a target on a workpiece maintained on a biased platen. The sputter gas is or includes krypton or xenon. The bias to the platen is selected to give a substantially flat XRD FWHM profile across the wafer and a stress in the film of less than or equal to ±5E10-8 dynes per cm².

This invention relates to a method of depositing aluminium nitride having a predetermined crystallographic orientation.

Aluminium nitride is becoming significantly important as a piezoelectric layer, for example as part of an acoustic wave device. As discussed in the applicant's U.S. patent application Ser. No. 09/548,014, the quality of the aluminium nitride, as a piezoelectric layer, is dependent on its crystallographic structure and in that case, it was appreciated that by treating the electrode, on to which the aluminium nitride layer is deposited, it was possible to improve the ordering of the crystallographic planes of the electrode and hence of the aluminium nitride.

However, there is a further characteristic of the aluminium nitride, which also has to be taken into account and this is the absolute stress level within the film of aluminium nitride, which, ideally, should be zero. Whilst this characteristic is related to the film orientation as measured by x-ray diffraction peak analysis they do not vary precisely one with the other. In addition the quality of film orientation may vary across the wafer, whereas stress is computed on a whole wafer basis.

It has been known that each of these qualities can be varied by altering the bias voltage of the platen, but experiments with argon/nitrogen reactive sputtering of aluminium have shown that if one applies sufficient bias to the substrate to achieve acceptable levels of stress, then the XRD full wave half maximum (FWHM) measured uniformity across the wafer is unacceptable.

The present invention consists in a method of depositing crystallographically orientated aluminium nitride, comprising sputter depositing from an aluminium target onto a work piece mounted on a platen, which can be negatively biased, wherein the inert sputter gas is or includes krypton or xenon and the bias to the platen is selected to give a substantially flat XRD FWHM profile across the wafer and a nominally zero stress within the range of ≦±5E10-8 dynes per cm².

The target may be of aluminium nitride, but more conveniently the method is operated in what is known as “target poisoning” mode whereby an aluminium target is poisoned by atomic nitrogen contained in the sputtering gas to form a target surface of aluminium nitride. For this the target needs to be powered using RF or pulsed DC. A third possibility is that sputtered aluminium can be nitrided in flight or on the wafer, but this will tend to lead to an amorphous structure and, if it does, will fall outside the invention.

If the “target poisoning” mode is used, then there has to be sufficient nitrogen in the sputter gas to ensure that a nitride layer is properly formed. If the nitrogen content is not sufficiently high, then an amorphous film will form. Thus the krypton:nitrogen ratio may be in the range 1:1˜0.6 and preferably 1:0.8. The total sputter gas flow rate may be between 30-100 sccm.

As has been mentioned above the target is preferably powered and the power supplied to the target may be in the range 1 to 10 Kw. Preferably the target is pulse DC powered at a pulse frequency of 75˜350 khz and a pulse width of up to 5000 nano seconds.

As will be indicated in detail below, for any particular configuration the appropriate bias can be determined empirically using the teaching of this Application, but typically the platen will be negatively bias in the range of approximately −30 to −50 volts and the substrate temperature should be less than 500° C.

A preferred process is:

Target Power—2 kw DC pulsed at 100 Khz with pulse width of 4000 nano seconds

Krypton/nitrogen ratio 1:0.8

Substrate bias −40 volts

Platen temperature 150° C.

Although the invention has been defined above it is to be understood that it includes any inventive combination of the features set out above or in the following description.

The invention may be performed in various ways and a specific embodiment will now be described, by way of example, with reference to the accompanying drawings, in which

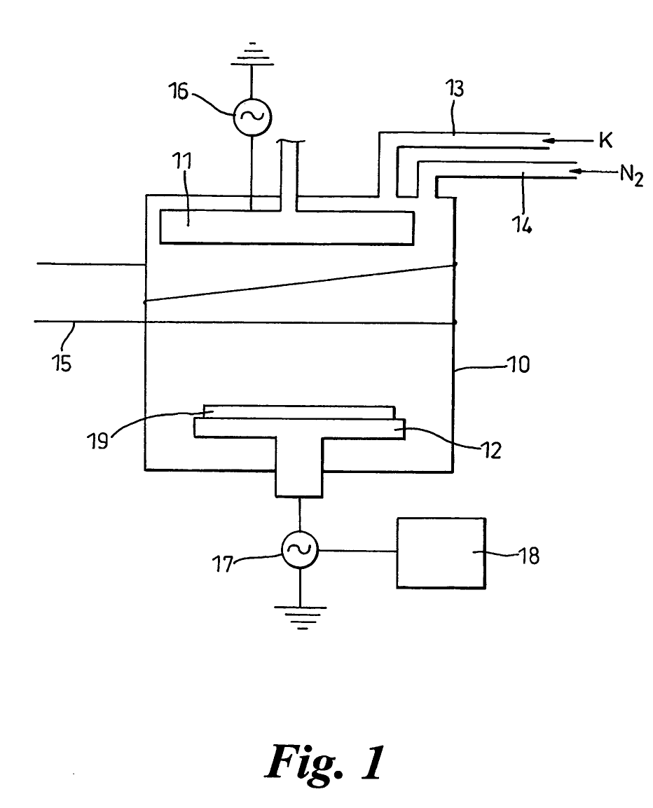

FIG. 1 is a schematic display of apparatus suitable for performing the invention;

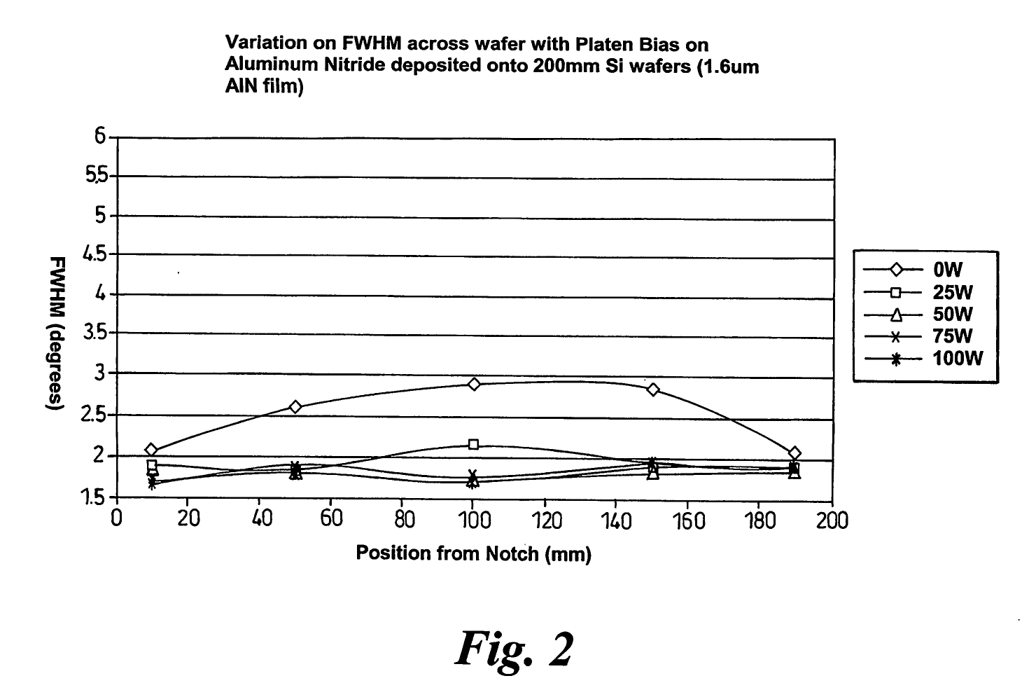

FIG. 2 illustrates variation in FWHM across a wafer (where argon is used as the inert sputter gas with nitrogen) for different levels of power supplied to the platen, which, for any particular set up, correspond to corresponding negative biases induced on the platen surface and

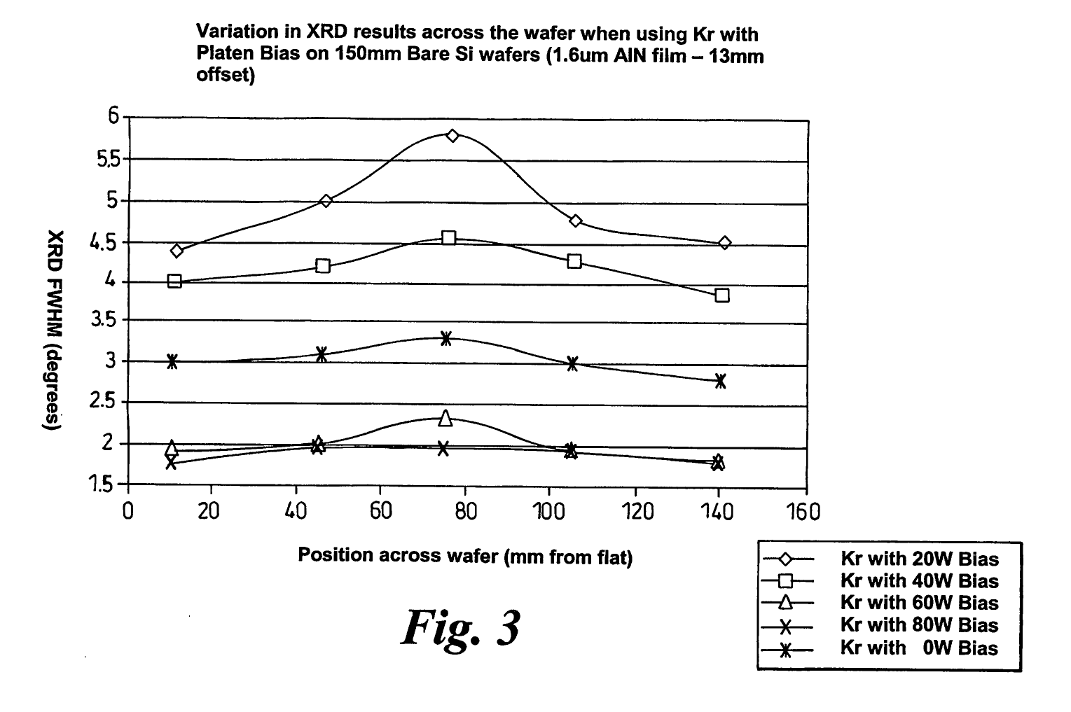

FIG. 3 is a corresponding figure showing XRD variations for different powers supplied to the platen using krypton as the inert sputter gas, with nitrogen.

As has been mentioned above for certain applications, for example BAW (bulk acoustic wave) filters, aluminium nitride films are required which display strong (002) orientation to produce the correct electrical characteristics required by these devices. The applicants have previously developed a process to achieve good orientation however it has been determined that the film quality varies between the centre and the edge of the wafer due to the film being less well orientated towards the edge. The applicants initial experiments with argon demonstrated how film orientation across a wafer varied with the applied platen bias. Thus the shape of an FWHM diameter scan varied as the platen bias was increased. When no bias is applied, the film orientation varies greatly from the edge of the wafer to the centre with a lower FWHM angle at the edge. With increasing platen bias, the FWHM angular plot gradually inverts. For argon/nitrogen mixes on 200 mm wafers, between 25 watts and 50 watts power supplied to the platen, in the applicants experimental set up, there would appear to be an optimum point where the FHWM angle is at its most uniform across the wafer. However, in this bias range, the stress in the film was too great to be useable.

For the purposes of BAW devices, nominally zero stress is sought, which is defined as ≦±5E10-8 dynes per cm².

The scan results for the argon process are illustrated in FIG. 2, in which the inversion of the FWHM angular profile across the wafer is clearly seen.

Turning to FIG. 1, the basic experimental set up for the present invention is now shown. Here a chamber 10, encloses an aluminium target 11 and a platen 12. Gas inputs 13, 14 are provided for krypton and nitrogen respectively and an outlet 15 is provided to a suitable vacuum pump (not shown). The target and platen are powered by respective power supplies 16, 17. A control 18 is provided for varying the power supplied to the platen 12 and hence varying the negative bias induced. A wafer 19 sits on the platen 12.

Using krypton as the inert sputter gas, the applicants established that the stress could be optimised at around a 70 watt platen bias, which is equivalent to a negative bias of around −40 volts. As can be seen from FIG. 3, between 60 and 80 watts a substantially flat FWHM angle profile will be achieved and so using krypton in this process window will not only provide a uniform FWHM angle which is much improved over the standard process, but also provide optimised stress characteristics.

It will be appreciated that the precise value for power supply to the platen may vary with wafer diameter, the depth of film to be deposited and the apparatus used for that deposition. However, it is clear that a person skilled in the art can identify the optimised bias voltage for stress and film orientation utilising the procedure set out above.

It should be understood that the use of krypton changes the bias to stress and bias to FWHM relationships thus enabling optimisation of stress and FWHM characteristics either simultaneously or as part of a multistep process, by using control of bias and gas composition as process variables.

In a two step process a first layer would be deposited to optimise crystallographic orientation and a second step would deposit the bulk layer optimised for stress. The relatively thin seed layer's stress characteristics would be dominated by the bulk layer above it, yet it would act as a seed layer enabling a preferred FWHM characteristic throughout the whole layer. The two process steps are characterised in that they operate with different bias levels and/or different gas mixtures with at least one of the layers been deposited with a gas mix consisting at least in part of krypton or xenon.

1. A method of depositing crystallographically orientated aluminium nitride comprising sputter depositing aluminium nitride from a target on a workpiece maintained on a platen, which can be negatively biased, wherein the sputter gas is or includes krypton or xenon and the bias to the platen is selected to give a substantially flat XRD FWHM profile across the wafer and a stress in the film of less than or equal to ±5E10-8 dynes per cm².

2. A method as claimed in claim 1 wherein the sputter gas is a mixture of krypton and/or xenon and nitrogen and the target is aluminium.

3. A method as claimed in claim 2 wherein the krypton:nitrogen ratio is in the range of 1:1 and 1:0.6.

4. A method as claimed in claim 1 wherein the sputter gas flow rate is between 30-100 sccm.

5. A method as claimed in claim 1 wherein the garget is DC pulse powered.

6. A method as claimed in claim 5 wherein the power supplied to the target is in the range of 1 to 10 kWDC pulsed.

7. A method as claimed in claim 1 wherein the bias to the platen is in the range of −30 to −50 volts.

8. A method of RF or pulsed DC sputter depositing a nonamorphous metallic layer wherein the sputter gas is or includes krypton or xenen, a bias is applied to the layer during deposition and the XRD FWHM profile of the layer across the substrate is constant to within 1/2° and the stress no greater than ±5E10-8 dynes cm².

9. A method as claimed in claim 1 wherein bias and sputter gas mixtures are varied between a first layer and a subsequently contiguous layer.

10. A method as claimed in claim 8 wherein the bias and/or sputter gas mixtures is adjusted to determine the crystallographic orientation in the first layer and the stress in the second layer.
